(19) United States
(12) Patent Application Publication
(10) Pub. No.: US 2016/0049394 A1
(43) Pub. Date: Feb. 18, 2016

(54) SEMICONDUCTOR DEVICE

(71) Applicant: SAMSUNG ELECTRONICS CO., LTD., Suwon-si (KR)

(72) Inventors: Heon-Jong SHIN, Yongin-si (KR); Deok-Han BAE, Anyang-si (KR); Dae-Hee WEON, Seongnam-si (KR); Hwi-Chan JUN, Yongin-si (KR)

(21) Appl. No.: 14/629,249

(22) Filed: Feb. 23, 2015

(30) Foreign Application Priority Data
Aug. 14, 2014 (KR) 10-2014-0106164

(51) Int. Cl. H01L 27/088; H01L 29/417; H01L 23/532; H01L 29/45; H01L 23/522; H01L 23/528

(52) U.S. Cl. CPC H01L 27/0886; H01L 23/5226; H01L 23/528; H01L 23/53266; H01L 29/45; H01L 29/41791

(57) ABSTRACT

A semiconductor device includes a transistor formed on a substrate and including a gate electrode and a source/drain, an interlayer insulating layer covering the transistor, a first contact hole formed in the interlayer insulating layer to expose a part of the transistor, a first barrier metal conformally formed on an inner surface of the first contact hole, a first conductive layer formed on the first barrier metal to fill the first contact hole, a second contact hole formed on the first conductive layer in the interlayer insulating layer and having a larger width than the first contact hole, a second barrier metal conformally formed on an inner surface of the second contact hole, and a second conductive layer formed on the second barrier metal to fill the second contact hole, wherein the second barrier metal is formed between the first conductive layer and the second conductive layer.

### CROSS-REFERENCE TO RELATED APPLICATIONS

This U.S. non-provisional patent application claims priority under 35 U.S.C. §119 to Korean Patent Application No. 10-2014-0106164, filed on Aug. 14, 2014 in the Korean Intellectual Property Office, the contents of which are herein incorporated by reference in their entirety.

### BACKGROUND

1. Field

Embodiments relate to a semiconductor device.

2. Discussion of Related Art

Recently, semiconductor devices have been developed in the direction where they can perform high-speed operation at low voltage, and processes of fabricating a semiconductor device have been developed in the direction where they can improve integrity of the semiconductor device. The improved integrity of the semiconductor device may cause the occurrence of a short channel effect in a field effect transistor (FET) that is one of the semiconductor devices. In order to overcome this, researches for fin field effect transistors (FinFET), in which channels are formed in a 3D spatial structure, have been actively made.

### SUMMARY

Embodiments provide a semiconductor device with improved operation characteristics.

Embodiments also provide a method for fabricating a semiconductor device with improved operation characteristics.

According to an aspect of embodiments, there is provided a semiconductor device including a transistor formed on a substrate and including a gate electrode and a source/drain, an interlayer insulating layer covering the transistor, a first contact hole formed in the interlayer insulating layer to expose a part of the transistor, a first barrier metal conformally formed on an inner surface of the first contact hole, a first conductive layer formed on the first barrier metal to fill the first contact hole, a second contact hole formed on the first conductive layer in the interlayer insulating layer and having a larger width than the first contact hole, a second barrier metal conformally formed on an inner surface of the second contact hole, and a second conductive layer formed on the second barrier metal to fill the second contact hole, wherein the second barrier metal is formed between the first conductive layer and the second conductive layer.

A width of the second conductive layer may be larger than a width of the first conductive layer.

A width of the second barrier metal may be larger than a width of an uppermost end of the first contact hole.

The first and second contact holes may have a tapered shape, respectively.

The first barrier metal may be connected to the source/drain of the transistor.

A lower surface of the first barrier metal may be lower than an upper surface of the source/drain.

The first and second conductive layers may be electrically connected to the gate electrode of the transistor.

Each of the first and second barrier metals may include at least one element of titanium (Ti), titanium nitride (TiN), tungsten nitride (WN), or any combination thereof.

Each of the first and second conductive layers may include tungsten (W).

According to another aspect of embodiments, there is provided a semiconductor device including a transistor formed on a substrate and including a gate structure and a source/drain, an interlayer insulating layer covering the transistor, a first contact hole formed in the interlayer insulating layer to expose a part of the transistor, a first barrier metal conformally formed on an inner surface of the first contact hole, a first conductive layer formed on the first barrier metal to fill the first contact hole, a second contact hole formed on the first conductive layer in the interlayer insulating layer and having a larger width than the first contact hole, a second barrier metal conformally formed on an inner surface of the second contact hole, and a second conductive layer formed on the second barrier metal to fill the second contact hole, wherein a part of the second contact hole overlaps a part of the gate structure.

A lower surface of the second contact hole may be higher than an upper surface of the gate structure.

The gate structure may include at least one element of a gate insulating layer, a conductive layer, a hard mask layer, a spacer, or any combination thereof.

The first and second conductive layers may be electrically connected to the source/drain.

The second contact hole formed on one side of the gate structure maybe arranged to be spaced apart from the second contact hole formed on the other side of the gate structure.

According to still another aspect of embodiments, there is provided a semiconductor device including a substrate on which a first active region and a second active region are defined, first and second gate structures formed on the substrate to cross the first and second active regions, an interlayer insulating layer covering the first and second active regions and the first and second gate structures, a first contact hole formed in the interlayer insulating layer to expose the source/drain in the first and second active regions or to expose the first and second gate structures, a first barrier metal conformally formed on an inner surface of the first contact hole, a first conductive layer formed on the first barrier metal to fill the first contact hole, a second contact hole formed on the first conductive layer in the interlayer insulating layer and having a larger width than the first contact hole, a second barrier metal conformally formed on an inner surface of the second contact hole, and a second conductive layer formed on the second barrier metal to fill the second contact hole, wherein the second barrier metal is formed between the first conductive layer and the second conductive layer.

The first contact hole may expose upper surfaces of the first and second gate structures, and the upper surfaces of the first and second gate structures may come in contact with a lower surface of the first barrier metal.

Each of the first and second gate structures may include a gate insulating layer, a lower metal gate electrode, and an upper metal gate electrode, which are sequentially formed.

The first contact hole may expose upper surfaces of the source/drain in the first active region and the source/drain in the second active region, and wherein the first and second conductive layers may be electrically connected to the source/drain in the first and second active region.

Each of the first and second active regions may include a first fin and a second fin.

Each of the first and second fins may include a recess formed on a part of the first or second fin, and elevated source/drain formed in the recess, wherein the first contact hole exposes the elevated source/drain.

### BRIEF DESCRIPTION OF THE DRAWINGS

The above and other objects, features and advantages will be more apparent from the following detailed description taken in conjunction with the accompanying drawings, in which:

FIG. 1 is a view illustrating a semiconductor device according to a first embodiment;

FIG. 2 is a view illustrating a semiconductor device according to a second embodiment;

FIG. 3 is a view illustrating a semiconductor device according to a third embodiment;

FIG. 4 is a cross-sectional view taken along line I-I of FIG. 3;

FIG. 5 is a view illustrating a semiconductor device according to a fourth embodiment;

FIG. 6 is a layout diagram illustrating a semiconductor device according to a fourth embodiment;

FIG. 7 is a cross-sectional view taken along line A-A of FIG. 6;

FIG. 8 is a cross-sectional view taken along line B-B of FIG. 6;

FIG. 9 is a cross-sectional view taken along line C-C of FIG. 6;

FIG. 10 is a circuit diagram explaining a semiconductor device according to some other embodiments;

FIG. 11 is a layout diagram of the semiconductor device of FIG. 10;

FIG. 12 is a diagram explaining a semiconductor device according to some other embodiments;

FIG. 13 is a diagram explaining a semiconductor device according to some other embodiments;

FIG. 14 is a block diagram of a SoC system that includes a semiconductor device according to embodiments;

FIG. 15 is a block diagram of an electronic system that includes a semiconductor device according to embodiments;

FIGS. 16 to 18 are views of exemplary semiconductor systems to which a semiconductor device according to some embodiments can be applied; and

FIGS. 19 to 27 are views of stages in a method for fabricating a semiconductor device according to an embodiment.

### DETAILED DESCRIPTION OF THE EMBODIMENTS

Advantages and features of embodiments and methods of accomplishing the same may be understood more readily by reference to the following detailed description of preferred embodiments and the accompanying drawings. Embodiments may, however, be embodied in many different forms and should not be construed as being limited to those set forth herein. Rather, these embodiments are provided so that this disclosure will be thorough and complete and will fully convey exemplary implementations to those skilled in the art, and embodiments will only be defined by the appended claims. Like reference numerals refer to like elements throughout the specification.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and are not intended to limit the embodiments.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

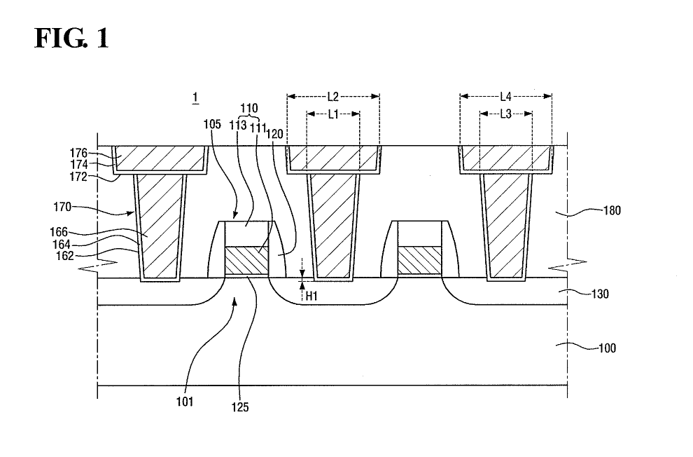

Hereinafter, referring to FIGS. 1 to 27, a semiconductor device and a method for fabricating the same according to some embodiments will be described.

FIG. 1 is a view illustrating a semiconductor device according to a first embodiment.

Referring to FIG. 1, a semiconductor device 1 includes a substrate 100, a transistor 101, a contact plug 170, and an interlayer insulating layer 180.

The substrate 100 may be made of, for example, bulk silicon or SOI (Silicon-On-Insulator). Unlike this, the substrate 100 may be a silicon substrate, or may include another material, such as silicon germanium, indium antimonide, lead telluride, indium arsenide, indium phosphide, gallium arsenide, or gallium antimonide. Further, the substrate 100 may be provided by forming an epitaxial layer on a base substrate. However, embodiments are not limited thereto.

The transistor 101 includes a gate structure 105, and a source/drain 130.

The source/drain 130 may be formed in the substrate 100 between adjacent gate structures 105. Although not clearly illustrated in the drawing, the source/drain 130 may be formed in an active layer. The source/drain 130 may include silicon or germanium that is an element semiconductor material. Further, the source/drain 130 may include compound semiconductor, and for example, may include group IV-IV compound semiconductor or group III-V compound semiconductor. Specifically, according to the group IV-IV compound semiconductor, the epitaxial layer may be made of a binary compound including at least two of carbon (C), silicon (Si), germanium (Ge), and tin (Sn), a ternary compound, or a compound including the above-described elements doped with group IV elements. According to the group III-V compound semiconductor, the epitaxial layer may be made of a binary compound formed through combination of at least one of group III elements, such as aluminum (Al), gallium (Ga), and indium (In), and one of group V elements, such as phosphorus (P), arsenide (As), and antimony (Sb), a ternary compound, or a quaternary compound. Although not illustrated in the drawing, the source/drain 130 may be formed in an LDD structure, but embodiments are not limited thereto.

The gate structure 105 may include a gate electrode 110, a spacer 120, and a gate insulating layer 125.

The gate insulating layer 125 may be arranged between the substrate 100 and the gate electrode 110. The gate insulating layer 125 may include a high-k layer. If the gate insulating layer 125 is the high-k layer, the gate insulating layer 125 may be made of a material having high dielectric constant. In some embodiments, the material having high dielectric constant may be, for example, HfO₂, Al₂O3, ZrO₂, or TaO₂, but embodiments are not limited thereto.

The gate electrode 110 may include a conductive layer 111 and a hard mask layer 113. The conductive layer 111 may be composed of a single conductive layer 111, such as a polysilicon layer, a silicide layer, or a metal layer, or a multilayer in which that above-described layers are laminated. The gate electrode 110 may include the hard mask layer 113 provided on an upper portion of the conductive layer 111.

The spacer 120 may be arranged on at least one side of the gate electrode 110. Specifically, as illustrated in FIG. 1, the spacer 120 may be arranged on both sides of the gate electrode 110. The spacer 120 may include at least one of a nitride layer and an oxynitride layer. FIG. 1 illustrates that one side surface of the spacer 120 is curved, but embodiments are not limited thereto. The shape of the spacer 120 may be differently modified without limits. For example, in some embodiments, the spacer 175 may be modified to be in “I” shape or in “L” shape unlike that as illustrated in the drawing.

The interlayer insulating layer 180 may be formed on the semiconductor substrate 100. The interlayer insulating layer 180 may be formed to cover the transistor 101. The interlayer insulating layer 180 may be in charge of electrical insulation between semiconductor elements provided on a lower portion of the interlayer insulating layer 180 and a semiconductor element provided on an upper portion of the interlayer insulating layer 180. The interlayer insulating layer 180 may be formed using silicon oxide, such as BSG (BoroSilicate Glass), PSG (PhosphoSilicate Glass), BPSG (BoroPhosphoSilicate Glass), USG (Undoped Silicate Glass), TEOS (TetraEthylOrthoSilicate Glass), or HDP-CVD (High Density Plasma-CVD). However, embodiments are not limited thereto.

The contact plug 170 may include a first contact hole 162, a second contact hole 172, a first barrier metal 164, a second barrier metal 174, a first conductive layer 166, and a second conductive layer 176.

The first contact hole 162 may be formed in the interlayer insulating layer 180, and may expose a part of the transistor 101.

The first contact hole 162 may expose the gate structure 105 or the source/drain 130 of the transistor 101. The first contact hole 162 may be formed by forming a photoresist pattern (not illustrated) for masking the remaining portion except for a contact hole forming region on the interlayer insulating layer 180 and by etching the contact hole forming region that is exposed by the photoresist pattern (not illustrated). However, embodiments are not limited thereto. Hereinafter, the first contact hole 162 for exposing the source/drain 130 will be described as an example.

The first contact hole 162 may be formed in a tapered shape. That is, the first contact hole 162 may be formed in a trapezoidal shape or in a reversed trapezoidal shape. However, embodiments are not limited thereto. The first contact hole 162 may be formed in a rectangular shape. The first contact hole 162 may be formed to etch a part of the source/drain 130. For example, the first contact hole 162 may be formed to have a first depth H1 from an upper surface of the source/drain 130. However, embodiments are not limited thereto.

The first barrier metal 164 may be conformally formed on an inner surface of the first contact hole 162. That is, the first barrier metal 164 may be formed on both side surfaces and a lower surface of the first contact hole 162 with a predetermined thickness. The first barrier metal 164 may include titanium (Ti), titanium nitride (TiN), or tungsten nitride (WN). The first barrier metal 164 may be formed using a PVD, CVD, or ILD method. However, embodiments are not limited thereto.

The first conductive layer 166 may be formed on the first barrier metal 164. The first conductive layer 166 may be formed to completely fill the inside of the first contact hole 162. In the drawing, it is illustrated that the lower surface of the first conductive layer 166 and the upper surface of the source/drain 130 have the same height, but embodiments are not limited thereto. The lower surface of the first conductive layer 166 may be formed to be higher or lower than the upper surface of the source/drain 130. The upper surface of the first conductive layer 166 may be arranged on the same plane as the upper surface of the first barrier metal 164. The first conductive layer 166 may be electrically connected to the source/drain 130. The first conductive layer 166 may include tungsten (W). However, embodiments are not limited thereto, and for example, the first conductive layer 166 may include at least one of polysilicon, metal silicide compound, conductive metal nitride, and metal.

The second contact hole 172 may be formed on the first conductive layer 166 in the interlayer insulating layer 180, and may have a width that is larger than the width of the first contact hole 162. Specifically, the lower surface of the second contact hole 172 may come in contact with the upper surface of the first contact hole 162. The width L2 of the lower surface of the second contact hole 172 may be larger than the width L1 of the upper surface of the first contact hole 162. In the same manner as the first contact hole, the second contact hole 172 may be formed in a tapered shape. That is, the second contact hole 172 may be formed in a trapezoidal shape or in a reversed trapezoidal shape. However, embodiments are not limited thereto. The second contact hole 172 may be formed in a rectangular shape.

The second contact hole 172 may be formed using an isotropic etching process. Specifically, the second contact hole 172 may be formed by etching the interlayer insulating layer 180, and the interlayer insulating layer 180 may be etched using a dry etching process or a wet etching process. Accordingly, the height of the interlayer insulating layer 180 is lowered, and the second contact hole 172 is formed on the upper portion of the first contact hole 162. However, embodiments are not limited thereto.

The second barrier metal 174 may be conformally formed on an inner surface of the second contact hole 172. In the same manner as the first barrier metal 164, the second barrier metal 174 may be formed on both side surfaces and a lower surface of the second contact hole 172 with a predetermined thickness. The second barrier metal 174 may be formed between the first conductive layer 166 and the second conductive layer 176. The width L2 of the second barrier metal 174 may be larger than the width L3 of the uppermost end of the first contact hole 162. The second barrier metal 174 may include titanium (Ti), titanium nitride (TiN), or tungsten nitride (WN). The second barrier metal 174 may be formed using a PVD, CVD, or ILD method. However, embodiments are not limited thereto.

The second conductive layer 176 may be formed on the second barrier metal 174. The second conductive layer 176 may be formed to completely fill the inside of the second contact hole 172. The upper surface of the second conductive layer 176 may be arranged on the same plane as the upper surface of the interlayer insulating layer 180. The width of the second conductive layer 176 may be larger than the width of the first conductive layer 166. For example, the width L4 of the lower surface of the second conductive layer 176 may be larger than the width L3 of the upper surface of the first conductive layer 166. The second conductive layer 176 may be electrically connected to the source/drain 130. The second conductive layer 176 may include tungsten (W). However, embodiments are not limited thereto, and for example, the second conductive layer 176 may include at least one of polysilicon, metal silicide compound, conductive metal nitride, and metal.

In the foregoing description, it is assumed that the contact plug 170 is electrically connected to the source/drain 130, but embodiments are not limited thereto. The contact plug 170 may also be formed on the gate structure 105 in the same shape and method. Through this, the contact plug 170 can be electrically connected to the gate structure 105. However, embodiments are not limited thereto.

In the semiconductor device 1 according to an embodiment, only the upper end portion of the contact plug 170 may be selectively largely formed. Accordingly, although not clearly illustrated in the drawing, as the upper end portion of the contact plug 170 is increased, the contact area with a via that is connected to the contact plug 170 may be increased, and through this, interface resistance between the contact plug 170 and the via can be lowered. The semiconductor device 1 according to embodiments does not require an additional lithography process, but uses the existing process mostly as it is. Accordingly, the contact plug 170 can be implemented without greatly increasing the production costs.

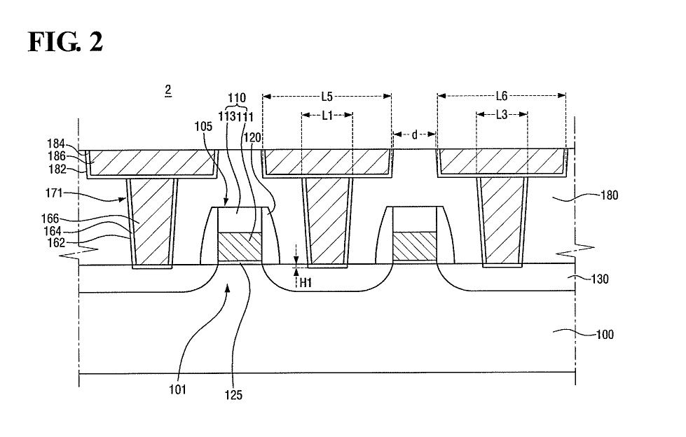

FIG. 2 is a view illustrating a semiconductor device according to a second embodiment. For convenience in explanation, hereinafter, the duplicate explanation of the same items as those according to the above-described embodiment will be omitted, and explanation will be made around the different points between this embodiment and the above-described embodiment.

Referring to FIG. 2, a semiconductor device 2 according to the second embodiment may be formed in substantially the same manner as that of the semiconductor device as described above with reference to FIG. 1.

A semiconductor device 2 includes a substrate 100, a transistor 101, a contact plug 171, and an interlayer insulating layer 180. The transistor 101 includes a gate structure 105, and a source/drain 130. The contact plug 171 may include a first contact hole 162, a second contact hole 182, a first barrier metal 164, a second barrier metal 184, a first conductive layer 166, and a second conductive layer 186.

The second contact hole 182 may be formed on the first conductive layer 166 in the interlayer insulating layer 180, and may have a width that is larger than the width of the first contact hole 162. Specifically, a part of the second contact hole 182 may overlap a part of the gate structure 105. That is, the width L5 of the second contact hole 182 may be larger than the width L1 of the first contact hole 162, and may be larger than the width L2 of the second contact hole 172 of the semiconductor device 1 as described above with reference to FIG. 1. Further, the width L6 of the lower surface of the second conductive layer 186 may be larger than the width L3 of the upper surface of the first conductive layer 166. Through this, in the case where a plurality of contact plugs 171 exist, the distance d between the second contact holes 182 is further decreased, and the contact area with a via connected to the contact plug 171 is further increased. Accordingly, the interface resistance between the contact plug 171 and the via can be further lowered.

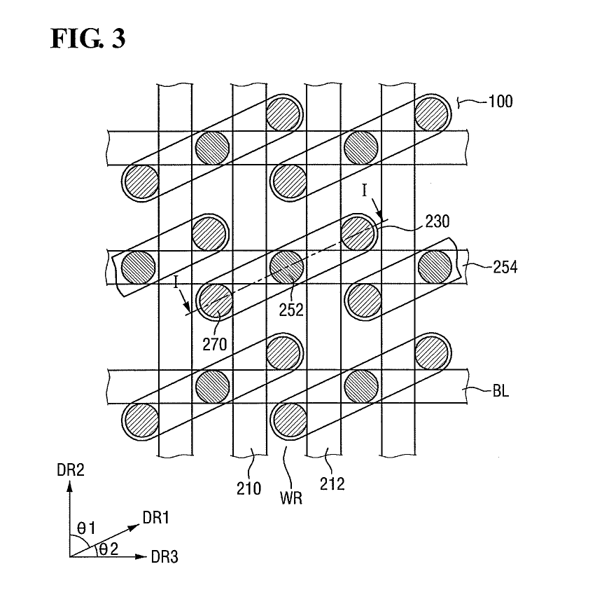

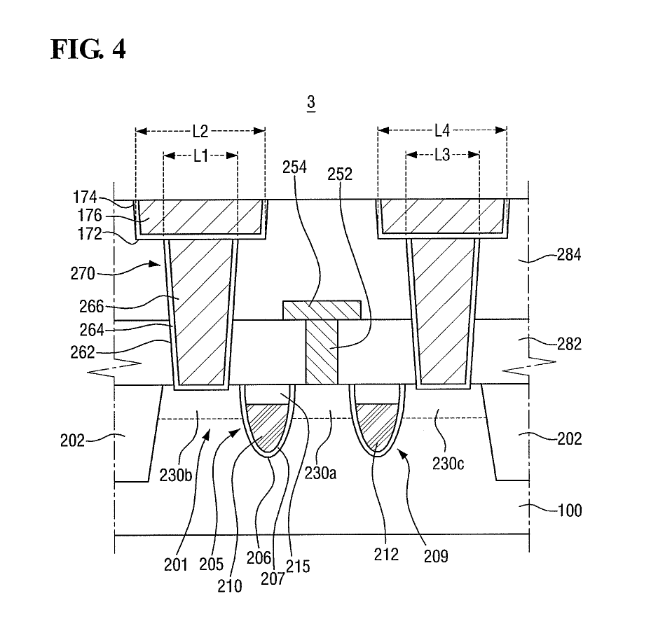

FIG. 3 is a view illustrating a semiconductor device according to a third embodiment, and FIG. 4 is a cross-sectional view taken along line I-I of FIG. 3. For convenience in explanation, hereinafter, the duplicate explanation of the same items as those according to the above-described embodiment will be omitted, and explanation will be made around the different points between this embodiment and the above-described embodiment.

Referring to FIG. 3, a semiconductor device 3 includes a unit active region 230.

The unit active region 230 is formed to extend in a first direction DR1, a word line WR is formed to extend in a second direction DR2 that forms an acute angle with respect to the first direction DR1, and a bit line 254 is formed to extend in a third direction DR3 that forms an acute angle with respect to the first direction DR1.

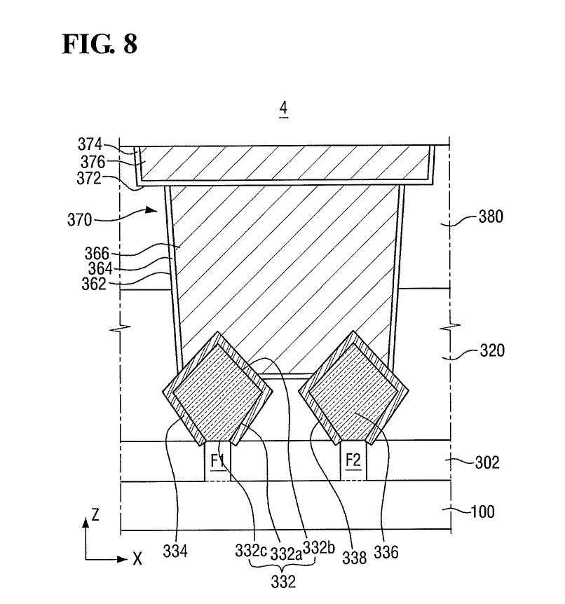

Here, the angle, which is formed between a specific direction and another specific direction, means a small one of two angles that are formed as two directions cross each other. For example, if it is assumed that the angles that are created through crossing of two directions are 120° and 60°, the angle means 60°. Accordingly, as illustrated in FIG. 8, the angle formed between the first direction DR1 and the second direction DR2 becomes θ1, and the angle formed between the first direction DR1 and the third direction DR3 becomes θ2.

As described above, the reason why 01 and/or 02 are made to form acute angles is to heighten integrity of memory cells. In this case, a distance between contact plugs 170 and 270, which connect a bit line 254, the unit active region 230, and a capacitor (not illustrated) to each other, can be secured as the size of the unit active region 230 is reduced. The angles θ1 and θ2 may be, for example, 45° and 45°, 30° and 60°, or 60° and 30°, respectively, but are not limited thereto.

Referring to FIG. 4, the semiconductor device 3 includes a substrate 100, an isolation layer 202, a transistor 201, a contact plug 270, and interlayer insulating layers 282 and 284. The transistor 201 may include a BCAT transistor 201.

The isolation layer 202 is formed in the substrate 100 to define the unit active region 230. The isolation layer 202 may have a STI (Shallow Trench Isolation) structure, which has superior isolation characteristics, a small occupation area, and the advantage of high integration, but is not limited thereto. The isolation layer 202 may include, for example, at least one of silicon oxide, silicon nitride, silicon oxynitride, and a combination thereof.

The transistor 201 includes a gate structure 205, and a source/drain 230. The gate structure 205 may include a trench 206, a gate insulating layer 207, a gate electrode 210, and a capping layer 215.

The trench 206 is formed in the substrate 100 of the unit active region 230. The trench 206 may be various shapes. For example, as illustrated, the trench 206 may have a round connection portion between a bottom surface and a side wall thereof. Further, the trench 206 may have a side wall that is tilted at a predetermined angle.

The gate insulating layer 207 may be conformally formed along the trench. The gate insulating layer may include, for example, silicon oxide, silicon nitride, or silicon oxynitride, or may include a high-k material. The high-k material may include, for example, at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but is not limited thereto.

The gate electrode 210 may be formed to fill at least a part of the trench 206 on which the gate insulating layer 207 is formed. The gate electrode 210 may be in a recessed shape. That is, the upper surface of the gate electrode 210 may be lower than the upper surface of the substrate 100. The gate electrode 210 may include a conductive material, such as metal or polysilicon, but is not limited thereto.

The capping layer 215 may be formed to fill the remainder of the trench 206 on which the gate electrode 210 is formed. The capping layer 215 may include, for example, at least one of silicon oxide, silicon nitride, and silicon oxynitride.

The sources/drains 230a, 230b, and 230c may be formed between the gate structures 205 and 209 or between the gate structures 205 and 209 and the isolation layer 202.

The contact plug 270 may include a first contact hole 262, a second contact hole 272, a first barrier metal 264, a second barrier metal 274, a first conductive layer 266, and a second conductive layer 276. The contact plug 270 may be substantially the same as the contact plugs 170 and 171 of the semiconductor devices 1 and 2 as described above with reference to FIGS. 1 and 2.

FIG. 4 illustrates that the contact plug 270 is electrically connected to the source/drain 130, but embodiments are not limited thereto. The contact plug 270 may also be formed on the gate structure 205 in the same shape and method. Through this, the contact plug 270 can be electrically connected to the gate structure 205. However, embodiments are not limited thereto.

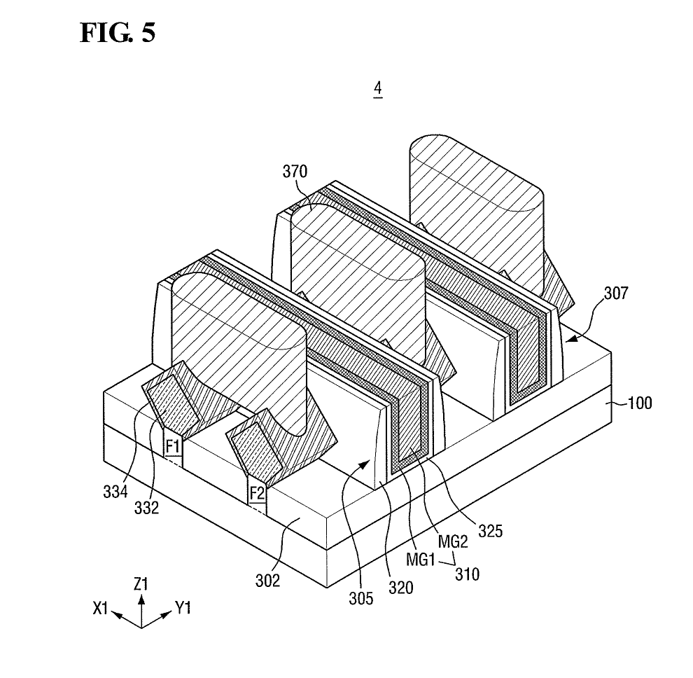

FIG. 5 is a view illustrating a semiconductor device according to a fourth embodiment.

Referring to FIG. 5, a semiconductor device 4 may include a substrate 100, a first fin F1, a second fin F2, a gate electrode 310, an elevated source/drain 130, a metal alloy layer 334, a contact plug 370, and an isolation layer 302. Specifically, the semiconductor device 4 may include a multi-gate structure (e.g., FinFET or GAA (Gate All Around) structure).

Specifically, the substrate 100 may be made of at least one semiconductor material selected from the group including Si, Ge, SiGe, GaP, GaAs, SiC, SiGeC, InAs, and InP. Further, the substrate 100 may be a SOI (Silicon On Insulator) substrate. Although not clearly illustrated in the drawing, a first active region (not illustrated) and a second active region (not illustrated) may be defined on the substrate 100.

The first fin F1 and the second fin F2 may extend long in a second direction Y. The first fin F1 may be a part of the substrate 100, and may include an epitaxial layer that is grown from the substrate 100. The isolation layer 302 may cover a side surface of the first fin F1. Although not clearly illustrated in the drawing, the first active region (not illustrated) may include the first fin F1, and the second active region (not illustrated) may include the second fin F2.

The gate electrode 310 may be formed on the first fin F1 and the second fin F2 to cross the first fin F1 and the second fin F2. The gate electrode 310 may extend in a first direction X.

The gate electrode 310 may include metal layers MG1 and MG2. As illustrated, two or more metal layers MG1 and MG2 may be laminated to provide the gate electrode. The metal layer MG1 may serve to adjust a work function, and the second metal layer MG2 may serve to fill a space formed by the metal layer MG1. For example, the metal layer MG1 may include at least one of TiN, TaN, TiC, and TaC. Further, the second metal layer MG2 may include W or Al. Further, the gate electrode 310 may be made of Si or SiGe, which is not metal. The gate electrode 310 as described above may be formed, for example, through a replacement process, but is not limited thereto.

The gate insulating layer 325 may be formed between the first and second fins F1 and F2 and the gate electrode 310. The gate insulating layer 325 may be formed on upper portions of the upper surfaces and the side surfaces of the first and second fins F1 and F2. Further, the gate insulating layer 325 may be arranged between the gate electrode 310 and the isolation layer 302. The gate insulating layer 325 as described above may include a high-k material having higher dielectric constant than the dielectric constant of the silicon oxide layer. For example, the gate insulating layer 325 may include HfO₂, ZrO₂, or Ta₂O₅.

The spacer 320 may include at least one of a nitride layer and an oxynitride layer.

The elevated source/drain 332 may be formed on both sides of the gate electrode 310 and the first and second fins F1 and F2. The elevated source/drain 332 may come in contact with the spacer 320 and side surfaces of the first and second fins F1 and F2.

On the other hand, the elevated source/drain 332 may have various shapes. For example, the elevated source/drain 332 may have at least one of a diamond shape, a circular shape, and a rectangular shape.

For example, as illustrated in FIG. 8, the elevated source/drain 332 may include a side wall 332a, an upper surface 332b, and a lower surface 332c. The lower surface 332c is a region that comes in contact with the first fin F1, and the side wall 332a is a region that is connected to the lower surface 332c. The side wall 332a may be tilted and may not be seen from an upper side depending on its shape. That is, in FIG. 8, the right side wall 332a may form an acute angle with respect to the upper surface of the first fin F1 in a counterclockwise direction. The upper surface 332b is a region that is connected to the side wall 332a, and may mainly come in contact with the contact plug 370.

If the semiconductor device 4 according to this embodiment is a PMOS transistor, the elevated source/drain 332 may include a compression stress material. For example, the compression stress material may be a material having higher lattice constant than the lattice constant of Si, and for example, SiGe. The compression stress material may apply compression stress to the first and second fins F1 and F2 to improve mobility of carriers of a channel region.

Unlike this, if the semiconductor device 4 is an NMOS transistor, the elevated source/drain 332 may be made of the same material as the material of the substrate 100 or a tension stress material. For example, if the substrate 100 is Si, the elevated source/drain 332 may be Si, or a material (e.g., SiC) having lower lattice constant than the lattice constant of Si.

The metal alloy layer 334 may be formed on the upper surface 332b and the side wall 332a of the elevated source/drain 332. The lower surface 332c of the elevated source/drain 332 comes in contact with the first fin F1, and thus the metal alloy layer 334 may not be formed thereon.

Even if the side wall 332a of the elevated source/drain 332 is tilted, the metal alloy layer 334 can be formed on the side wall 332a. The metal alloy layer 334 may include, for example, silicide. The metal alloy layer 334 can be completed by forming a metal layer on the elevated source/drain 332 in a plating method, performing heat treatment, and then making the elevated source/drain 332 and the metal layer react with each other to form the silicide. Since the plating method is used, the silicide can be formed on the side wall 332a and the upper surface 332b of the elevated source/drain 332 regardless of the shape of the elevated source/drain 332. In accordance with the kind of the metal layer, electroless plating or electroplating may be used.

Further, the metal alloy layer 334 may include not only a contact surface that comes in contact with the contact plug 370 but also a non-contact surface that does not come in contact with the contact plug 370. That is, the metal alloy layer 334 may be formed even on a region the does not come in contact with the contact plug 370.

The metal alloy layer 334 may be formed along the circumference of the elevated source/drain 332 to come in direct contact with the first fin F1 and the contact 370.

The contact plug 370 electrically connects wires to the elevated source/drain 332. The contact 370 may be formed using, for example, Al, Cu, or W, but is not limited thereto. The contact 370 may be formed to penetrate the first interlayer insulating layer 382 and the second interlayer insulating layer 382, but is not limited thereto. For example, as illustrated in FIG. 3, the upper surface of the first interlayer insulating layer 382 may be in parallel to the upper surface of the gate electrode 310. The upper surfaces of the first interlayer insulating layer 382 and the gate electrode 310 may be in parallel to each other through a planarization process (e.g., CMP process). The second interlayer insulating layer 384 may be formed to cover the gate electrode 310. The interlayer insulating layer 382 and the second interlayer insulating layer 384 may include at least one of oxide, nitride, and oxynitride.

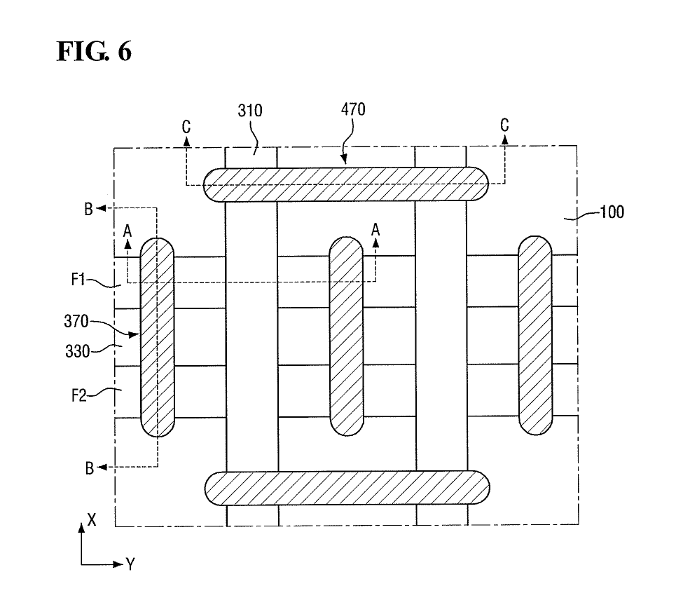

The contact plug 370 may include a first contact hole 362, a second contact hole 372, a first barrier metal 364, a second barrier metal 374, a first conductive layer 366, and a second conductive layer 376. The contact plug 370 may be formed in substantially the same manner as the contact plugs 170 and 171 of the semiconductor devices 1 and 2 as described above with reference to FIGS. 1 and 2. That is, although not clearly illustrated in the drawing, the contact plug 370 may be connected to the elevated source/drain 332 and the gate electrode 310. However, embodiments are not limited thereto, but the contact plug 370 may be connected to a plurality of elevated sources/drains 332 or a plurality of gate electrodes 310. The detailed explanation thereof will be made later with reference to FIGS. 6 to 9.

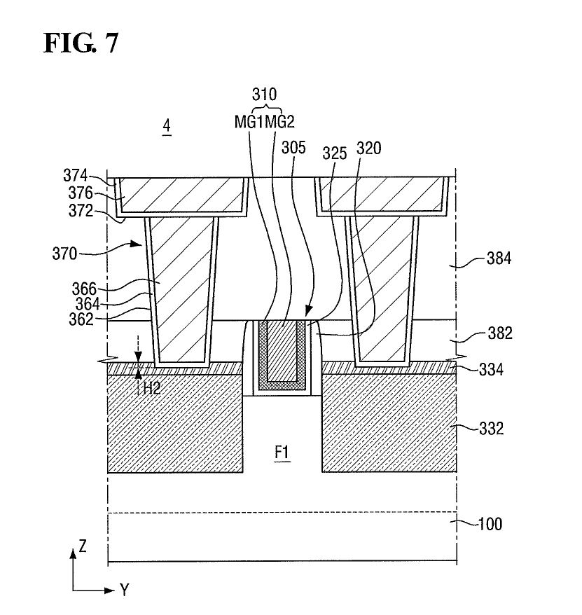

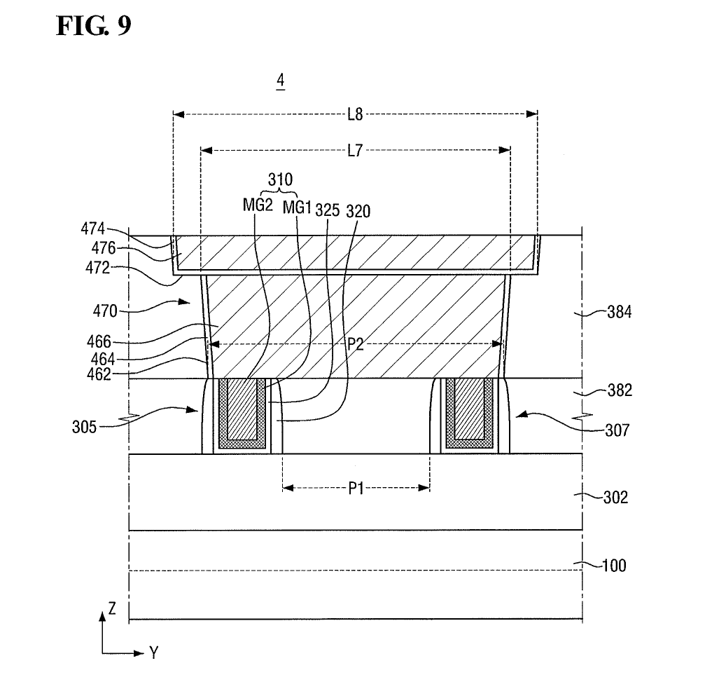

FIG. 6 is a layout diagram illustrating a semiconductor device according to a fourth embodiment, FIG. 7 is a cross-sectional view taken along line A-A of FIG. 6, FIG. 8 is a cross-sectional view taken along line B-B of FIG. 6, and FIG. 9 is a cross-sectional view taken along line C-C of FIG. 6. For convenience in explanation, hereinafter, the duplicate explanation of the same items as those according to the above-described embodiment will be omitted, and explanation will be made around the different points between this embodiment and the above-described embodiment.

Referring to FIGS. 6 and 7, the upper surface of the first interlayer insulating layer 382 may be formed to be in parallel to each other. For example, the upper surfaces of the first interlayer insulating layer 382 and the gate electrode 310 may be in parallel to each other through a planarization process (e.g., CMP process). The second interlayer insulating layers 384 and 372 may be formed to cover the gate electrode 310. A first spacer 320 may be formed on the side wall of the gate electrode 310. Here, a second spacer 320 may be formed along the side surface of the first spacer 320. That is, the second spacer 320 may be foamed in “I” shape, not in “L” shape.

The contact plug 370 may include a first contact hole 362, a second contact hole 372, a first barrier metal 364, a second barrier metal 374, a first conductive layer 366, and a second conductive layer 376. The contact plug 370 may be formed in substantially the same manner as the contact plugs 170 and 171 of the semiconductor devices 1 and 2 as described above with reference to FIGS. 1 and 2.

The first contact hole 362 may expose the elevated source/drain 332 and the metal alloy layer 334. The first contact hole 362 may be formed to penetrate the first interlayer insulating layer 382 and the second interlayer insulating layer 384. The first contact hole 362 may be formed in a tapered shape. The lower surface of the first contact hole 362 may be formed to be lower than the upper surface of the metal alloy layer 334. The first contact hole 362 may be formed to etch a part of the metal alloy layer 334 or the elevated source/drain 332. For example, the first contact hole 362 may be formed to have a second depth H2 from the upper surface of the metal alloy layer 334. However, embodiments are not limited thereto.

The first barrier metal 364 may be conformally formed on an inner surface of the first contact hole 362. That is, the first barrier metal 364 may be formed on both side surfaces and a lower surface of the first contact hole 362 with a predetermined thickness.

The second contact hole 372 may be formed on the first conductive layer 366 in the interlayer insulating layer 382, and may have a width that is larger than the width of the first contact hole 362. Specifically, the lower surface of the second contact hole 372 may come in contact with the upper surface of the first contact hole 362. The second contact hole 372 may be formed using an isotropic etching process. Specifically, the second contact hole 372 may be formed by etching the second interlayer insulating layer 384, and the second interlayer insulating layer 384 may be etched using a dry etching process or a wet etching process. Accordingly, the height of the second interlayer insulating layer 384 may be lowered, and the second contact hole 372 may be formed on the upper portion of the first contact hole 362.

The second barrier metal 374 may be conformally formed on an inner surface of the second contact hole 372. In the same manner as the first barrier metal 364, the second barrier metal 374 may be formed on both side surfaces and a lower surface of the second contact hole 372 with a predetermined thickness. The second barrier metal 374 may be formed between the first conductive layer 366 and the second conductive layer 376. The width of the second barrier metal 374 may be larger than the width of the uppermost end of the first contact hole 362.

The second conductive layer 376 may be formed on the second barrier metal 374. The second conductive layer 376 may be formed to completely fill the inside of the second contact hole 372. The upper surface of the second conductive layer 376 may be arranged on the same plane as the upper surface of the second interlayer insulating layer 384. For example, the upper surfaces of the second interlayer insulating layer 384 and the second conductive layer 376 may be in parallel to each other through a planarization process (e.g., CMP process).

Referring to FIGS. 6 to 8, the contact plug 370 may be connected to a plurality of elevated sources/drains 332. The elevated sources/drains 332 and 336 and the metal alloy layers 334 and 338 may be arranged on the first fin F1 and the second fin F2. The contact plug 370 may be electrically connected to the plurality of elevated sources/drains 332 and 336 and the metal alloy layers 334 and 338. Accordingly, the contact plug 370 may overlap the plurality of elevated sources/drains 332 and 336 and the metal alloy layers 334 and 338. For example, the second contact hole 372 of the contact plug 370 may completely overlap the elevated sources/drains 332 and 336 and the metal alloy layers 334 and 338.

The lower surface of the contact plug 370 may be formed to be lower than the upper surfaces of the elevated metal alloy layers 334 and 338 or the sources/drains 332 and 336. However, embodiments are not limited thereto.

Referring to FIGS. 6 and 9, a contact plug 470 of a gate may be formed in substantially the same manner as the contact plug 370 connected to the plurality of elevated source/drain 332 as described above.

A plurality of gate structures 305 and 307 may be arranged on the isolation layer 302. The upper surfaces of the gate structures 305 and 307 may be arranged on the same plane as the upper surface of the first interlayer insulating layer 382.

The contact plug 470 of the gate may include a first contact hole 462, a second contact hole 472, a first barrier metal 464, a second barrier metal 474, a first conductive layer 466, and a second conductive layer 476.

The first contact hole 462 may expose upper surfaces of the plurality of gate structures 305 and 307 or a part of the first interlayer insulating layer 382. That is, the first contact hole 462 may overlap the plurality of gate structures 305 and 307. The width P2 of the lower surface of the first contact hole 462 may be larger than the distance P1 between the plurality of gate structures 305 and 307.

In the same manner as the contact plug 370 that is connected to the plurality of elevated sources/drains 332, the first barrier metal 464 may be conformally formed on an inner surface of the first contact hole 462. The first conductive layer 466 may be formed to completely fill the inside of the first contact hole 462 on the first barrier metal 464. The first conductive layer 466 may be electrically connected to the plurality of gate structures 305 and 307.

The second contact hole 472 may be formed on the first conductive layer 466 in the second interlayer insulating layer 384. The width L8 of the lower portion of the second contact hole 472 may be larger than the width L7 of the uppermost end of the first contact hole 462. The lower surface of the second contact hole 472 may come in contact with the upper surface of the first contact hole 462. The second contact hole 472 may be formed using an isotropic etching process. Specifically, the second contact hole 472 may be formed by etching the second interlayer insulating layer 384, and the second interlayer insulating layer 384 may be etched using a dry etching process or a wet etching process. Accordingly, the height of the second interlayer insulating layer 384 may be lowered, and the second contact hole 472 may be formed on the upper portion of the first contact hole 462. However, embodiments are not limited thereto.

The second barrier metal 474 may be conformally formed on an inner surface of the second contact hole 472. The second conductive layer 476 may be formed on the second barrier layer 474 to completely fill the inside of the second contact hole 472. The upper surface of the second conductive layer 476 may be arranged on the same plane as the upper surface of the second interlayer insulating layer 384. However, embodiments are not limited thereto.

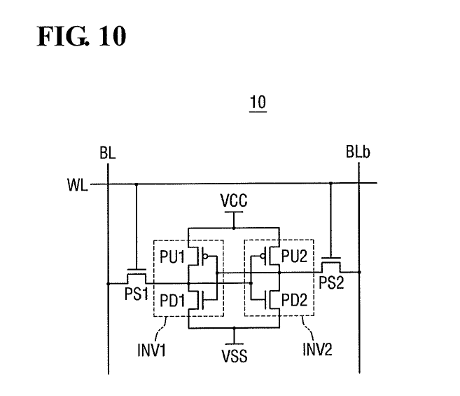

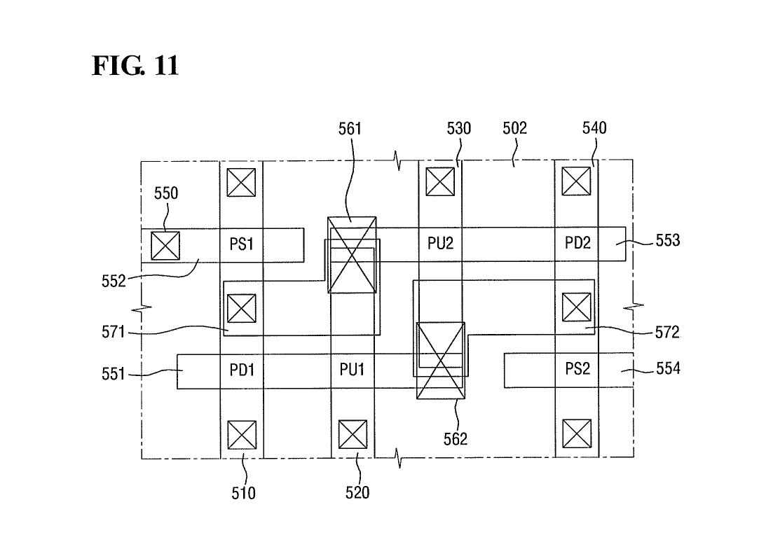

FIG. 10 is a circuit diagram explaining a semiconductor device according to some other embodiments, and FIG. 11 is a layout diagram of the semiconductor device illustrated in FIG. 10.

Hereinafter, duplicate explanation of the above-described embodiments will be omitted, and explanation will be made around different points between the some embodiments and the above-described embodiments.

Referring to FIGS. 10 and 11, a semiconductor device 10 may include a pair of inverters INV1 and INV2 connected in parallel between a power supply node Vcc and a ground node Vss, and a first path transistor PS1 and a second pass transistor PS2 connected to output nodes of the respective inverters INV1 and INV2. The first pass transistor PS1 and the second pass transistor PS2 may be connected to a bit line BL and a complementary bit line BLb. Gates of the first pass transistor PS1 and the second pass transistor PS2 may be connected to a word line WL.

The first inverter INV1 includes a first pull-up transistor PU1 and a first pull-down transistor PD1 which are connected in series, and the second inverter INV2 includes a second pull-up transistor PU2 and a second pull-down transistor PD2 which are connected in series. The first pull-up transistor PU1 and the second pull-up transistor PU2 may be PFET transistors, and the first pull-down transistor PD1 and the second pull-down transistor PD2 may be NFET transistors.

Further, the first inverter INV1 and the second inverter INV2 may constitute one latch circuit in a manner that an input node of the first inverter INV1 is connected to an output node of the second inverter INV2, and an input node of the second inverter INV2 is connected to an output node of the first inverter INV1.

Here, referring to FIGS. 10 and 11, a first active fin 510, a second active fin 520, a third active fin 530, and a fourth active fin 540, which are spaced apart from each other, may be formed to extend long in one direction (for example, upper/lower direction in FIG. 11). The extending length of the second active fin 520 and the third active fin 530 may be shorter than the extending length of the first active fin 510 and the fourth active fin 540.

Further, a first gate electrode 551, a second gate electrode 552, a third gate electrode 553, and a fourth gate electrode 554 may extend long in the other direction (for example, right/left direction in FIG. 11), and may be formed to cross the first to fourth active fins 510 to 540. Specifically, the first gate electrode 551 may be formed to completely cross the first active fin 510 and the second active fin 520 and to overlap a part of a vertical end of the third active fin 530. The third gate electrode 553 may be formed to completely cross the fourth active fin 540 and the third fin 530 and to overlap a part of a vertical end of the second active fin 520. The second gate electrode 552 and the fourth gate electrode 554 may be formed to cross the first active fin 510 and the fourth active fin 540, respectively.

As illustrated, the first pull-up transistor PU1 may be defined around a region where the first gate electrode 551 and the second active fin 520 cross each other, the first pull-down transistor PD 1 may be defined around a region where the first gate electrode 551 and the first active fin 510 cross each other, and the first pass transistor PS1 may be defined around a region where the second gate electrode 552 and the first active fin 510 cross each other. The second pull-up transistor PU2 may be defined around a region where the third gate electrode 553 and the third active fin 530 cross each other, the second pull-down transistor PD2 may be defined around a region where the third gate electrode 553 and the fourth active fin 540 cross each other, and the second pass transistor PS2 may be defined around a region where the fourth gate electrode 554 and the fourth active fin 540 cross each other.

Although not clearly illustrated, the source/drain may be formed on both sides of regions where the first to fourth gate electrodes 551 to 554 and the first to fourth active fins 510 to 540 cross each other, and a plurality of contacts 550 may be formed.

In addition, a first shared contact 561 may simultaneously connect the second active fin 520, the third gate electrode 553, and a wiring 571. A second shared contact 562 may simultaneously connect the third active fin 530, the first gate electrode 551, and a wiring 572.

The semiconductor device 10 may be used as, for example, a SRAM (Static Random Access Memory). Further, at least one transistor PU1 and PU2, PD1 and PD2, and PS1 and PS2 included in the semiconductor device 10 may adopt the configuration according to the embodiments of the semiconductor devices 1 to 4.

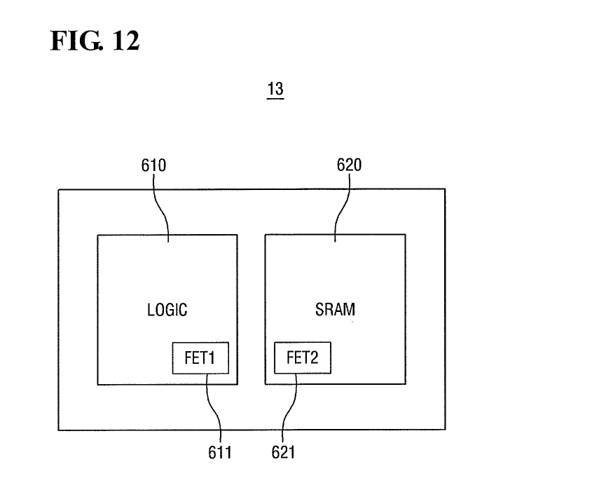

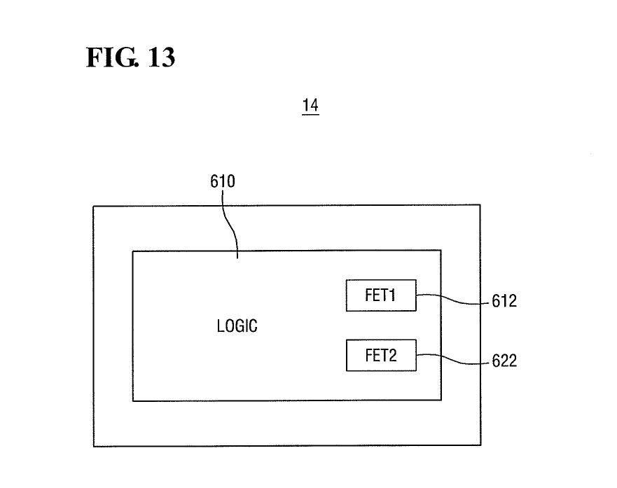

FIG. 12 is a circuit diagram explaining a semiconductor device according to some other embodiments, and FIG. 13 is a circuit diagram explaining a semiconductor device according to some other embodiments. Hereinafter, duplicate explanation of the above-described embodiments will be omitted, and explanation will be made around different points between the some embodiments and the above-described embodiments.

First, referring to FIG. 12, a semiconductor device 13 may include a logic area 610 and an SRAM formation area 620. An eleventh transistor 611 may be arranged on the logic area 610, and a twelfth transistor 621 may be arranged on the SRAM formation area 620.

In some embodiments, the eleventh transistor 611 and the twelfth transistor 621 may have different conduction types. Accordingly, if the transistor 101 as illustrated in FIG. 1 is adopted as the eleventh transistor 611, the transistor 201 as illustrated in FIG. 4 may be adopted as the twelfth transistor 621.

Further, in some other embodiments, the eleventh transistor 611 and the twelfth transistor 421 may have the same conduction type. In some embodiments, for example, any one of the semiconductor devices 1 to 4 may be adopted as the eleventh transistor 611 and the twelfth transistor 621.

Next, referring to FIG. 13, a semiconductor device 14 may include a logic area 610, and thirteenth and fourteenth transistors 612 and 622, which are different from each other, may be arranged in the logic area 610. On the other hand, although not separately illustrated, the thirteenth and fourteenth transistors 612 and 622, which are different from each other, may be arranged even in the SRAM region.

In the same manner, in some embodiments, any one of the semiconductor devices 1 to 4 may be adopted as the thirteenth and fourteenth transistors 612 and 622.

On the other hand, FIG. 13 exemplarily illustrates the logic area 610 and the

SRAM forming area 620, but embodiments are not limited thereto. For example, embodiments may be applied even to the logic area 610 and other regions where memories are formed (e.g., DRAM, MRAM, RRAM, and PRAM).

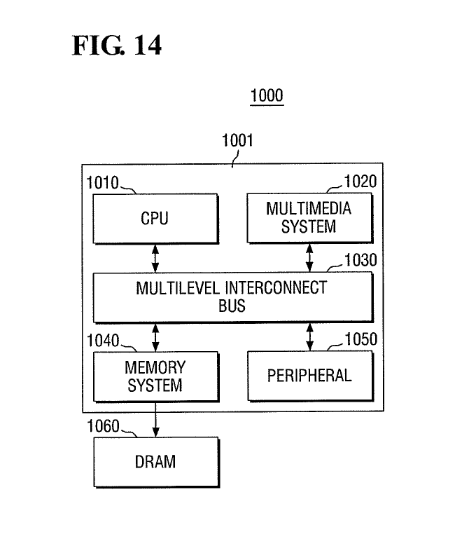

FIG. 14 is a block diagram of a SoC system that includes a semiconductor device according to embodiments.

Referring to FIG. 14, a SoC system 1000 includes an application processor 1001 and a DRAM 1060.

The application processor 1001 may include a central processing unit 1010, a multimedia system 1020, a bus 1030, a memory system 1040, and a peripheral circuit 1050.

The central processing unit 1010 may perform operations required to drive the

SoC system 1000. In some embodiments, the central processing unit 1010 may be configured in a multi-core environment including a plurality of cores.

The multimedia system 102 may be used when the SoC system 100 performs various kinds of multimedia functions. The multimedia system 1020 may include a 3D engine module, a video codec, a display system, a camera system, and a post-processor.

The bus 1030 may be used when the central processing unit 1010, the multimedia system 1020, the memory system 1040, and the peripheral circuit 1050 perform data communication with each other. In some embodiments, examples of the bus 1030 may include a multilayer AHB (Advanced High-performance Bus) and a multilayer AXI (Advanced eXtensible Interface), but embodiments are not limited thereto.

The memory system 1040 may provide an environment that is necessary when the application processor 1001 is connected to an external memory (e.g., DRAM 1060) to perform high-speed operation. In some embodiments, the memory system 1040 may include a separate controller (e.g., DRAM controller) for controlling the external memory (e.g., DRAM 1060).

The peripheral circuit 1050 may provide an environment that is necessary when the SoC system 1000 is smoothly connected to the external device (e.g., main board). Accordingly, the peripheral circuit 1050 may be provided with various interfaces for making the external device connected to the SoC system 1000 compatible.

The DRAM 1060 may function as an operating memory that is necessary when the application processor 1001 operates. In some embodiments, the DRAM 1060 may be arranged on an outside of the application processor 1001 as illustrated in the drawing. Specifically, the DRAM 1060 and the application processor 1001 may be packaged in the form of PoP (Package on Package).

At least one of the constituent elements of the SoC system 1000 may adopt any one of the semiconductor devices 1 to 4 according to the embodiments.

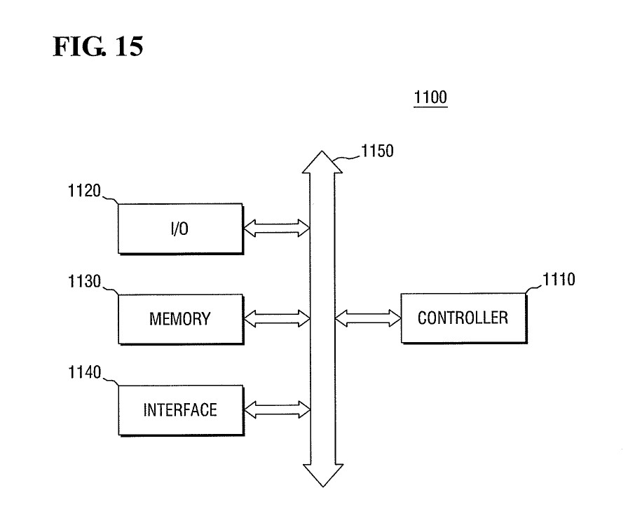

FIG. 15 is a block diagram of an electronic system that includes a semiconductor device according to embodiments.

Referring to FIG. 15, an electronic system 1100 according to an embodiment of may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to paths through which data is transferred.

The controller 1110 may include at least one of a microprocessor, a digital signal processor, a microcontroller, and logic elements that can perform similar functions. The I/O device 1120 may include a keypad, a keyboard, and a display device. The memory 1130 may store data and/or commands. The interface 1140 may function to transfer the data to a communication network or receive the data from the communication network. The interface 1140 may be of a wired or wireless type. For example, the interface 1140 may include an antenna or a wire/wireless transceiver.

Although not illustrated, the electronic system 1100 may further include a high-speed DRAM and/or SRAM as an operating memory for improving the operation of the controller 1110. In this case, as the operating memory, any one of the semiconductor devices 1 to 6 according to the above-described embodiments. Further, any one of the semiconductor devices 1 to 6 a may be provided in the memory 1130, or may be provided as a part of the controller 1110 or the I/O device 1120.

The electronic system 1100 may be applied to a PDA (Personal Digital

Assistant), a portable computer, a web tablet, a wireless phone, a mobile phone, a digital music player, a memory card, or all electronic devices that can transmit and/or receive information in wireless environments.

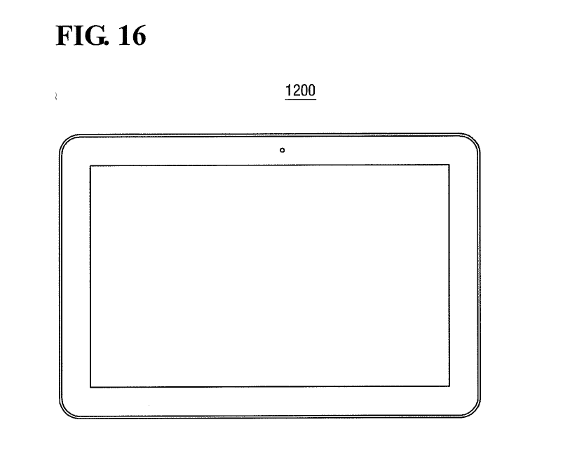

FIGS. 16 to 18 are views of exemplary semiconductor systems to which the semiconductor device according to some embodiments can be applied.

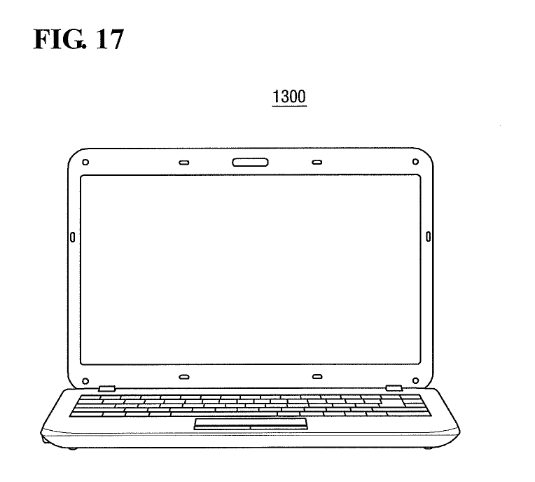

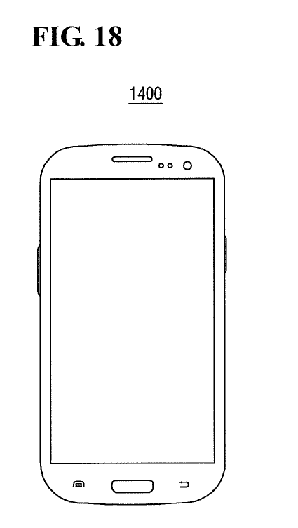

FIG. 16 illustrates a tablet PC 1200, FIG. 17 illustrates a notebook computer 1300, and FIG. 18 illustrates a smart phone 1400. At least one of the semiconductor devices 1 to 4 according to the embodiments may be used in the tablet PC 1200, the notebook computer 1300, or the smart phone 1400.

Further, it is apparent to those of skilled in the art that the semiconductor device according to some embodiments can be applied even to other integrated circuit devices that have not been exemplified. That is, although the tablet PC 1200, the notebook computer 1300, and the smart phone 1400 have been indicated as examples of the semiconductor system according to this embodiment, the examples of the semiconductor system according to this embodiment are not limited thereto. In some embodiments, the semiconductor system may be implemented as a computer, UMPC (Ultra Mobile PC), workstation, net-book, PDA (Personal Digital Assistant), portable computer, wireless phone, mobile phone, e-book, PMP (Portable Multimedia Player), portable game machine, navigation device, black box, digital camera, 3D television set, digital audio recorder, digital audio player, digital picture recorder, digital picture player, digital video recorder, or digital video player.

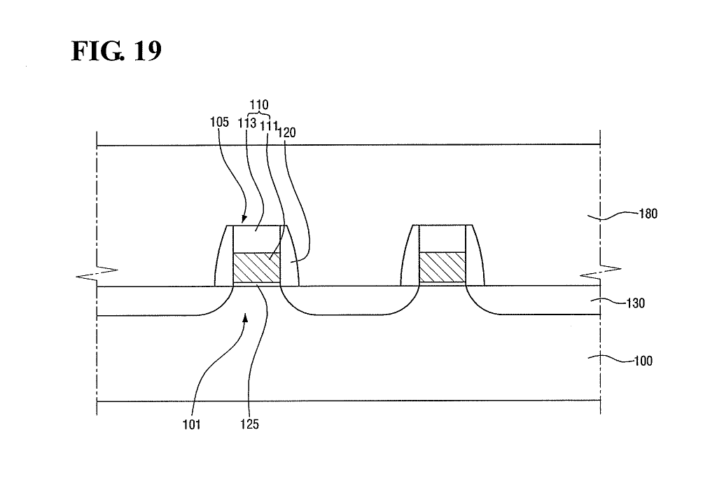

Hereinafter, referring to FIGS. 19 to 27, a method for fabricating a semiconductor device according to an embodiment will be described.

FIGS. 19 to 27 are views of intermediate steps explaining a method for fabricating a semiconductor device according to an embodiment.

First, referring to FIG. 19, a transistor 101 is formed on a substrate 100. The transistor 101 includes a gate structure 105, and a source/drain 130. The gate structure 105 may include a gate electrode 110, a spacer 120, and a gate insulating layer 125. The gate electrode 110 may include a conductive layer 111 and a hard mask layer 113.

The process of forming the transistor 101 on the substrate 100 may be a process well known in the art, and embodiments are not limited by such a fabricating method.

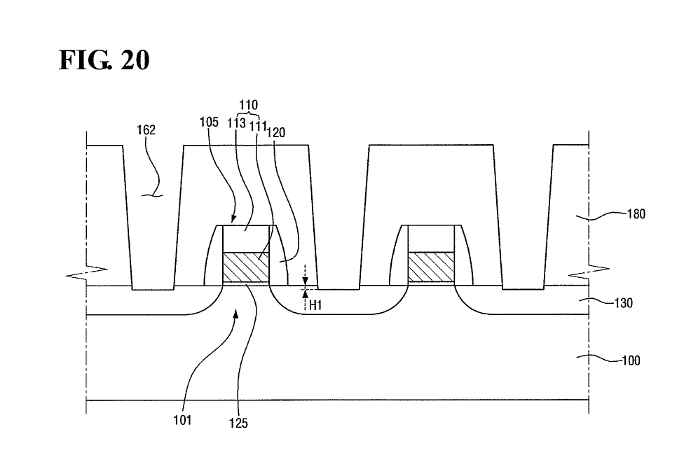

Then, referring to FIG. 20, an interlayer insulating layer 180 that covers the transistor 101 is formed. The interlayer insulating layer 180 may be formed to cover the gate structure 105 and the source/drain 130. The interlayer insulating layer 180 may be formed through a deposition process, such as chemical vapor deposition (CVD) as a single layer or a multilayer of oxide or nitride series. The interlayer insulating layer 180 may be in charge of electrical insulation between semiconductor elements provided on a lower portion of the interlayer insulating layer 180 and a semiconductor element provided on an upper portion of the interlayer insulating layer 180.

Then, a first contact hole 162 is formed in the interlayer insulating layer 180.

For example, the first contact hole 162 may be formed by forming a photoresist pattern (not illustrated) for masking the remaining portion except for a first contact hole forming region on the interlayer insulating layer 180 and by etching the contact hole forming region that is exposed by the photoresist pattern. However, embodiments are not limited thereto, and the first contact hole 162 may be formed to expose the gate structure 105.

For example, the first contact hole 162 may be formed in a tapered shape. Further, the first contact hole 162 may be formed to have a first depth H1 from the upper surface of the source/drain 130. However, embodiments are not limited thereto.

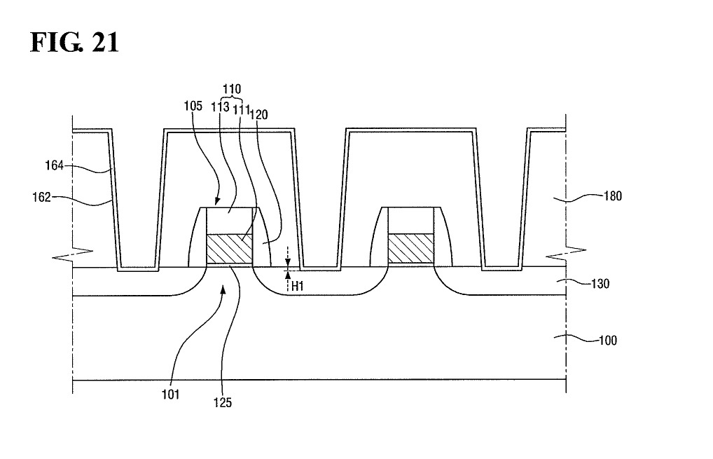

Then, referring to FIG. 21, a first barrier metal 164 is conformally formed on the interlayer insulating layer 180. Through this, the first barrier metal 164 may be conformally formed on an inner surface of the first contact hole 162. That is, the first barrier metal 164 may be formed on both side surfaces and a lower surface of the first contact hole 162 with a predetermined thickness. The first barrier metal 164 may include titanium (Ti), titanium nitride (TiN), or tungsten nitride (WN). The first barrier metal 164 may be formed using a PVD, CVD, or ILD method.

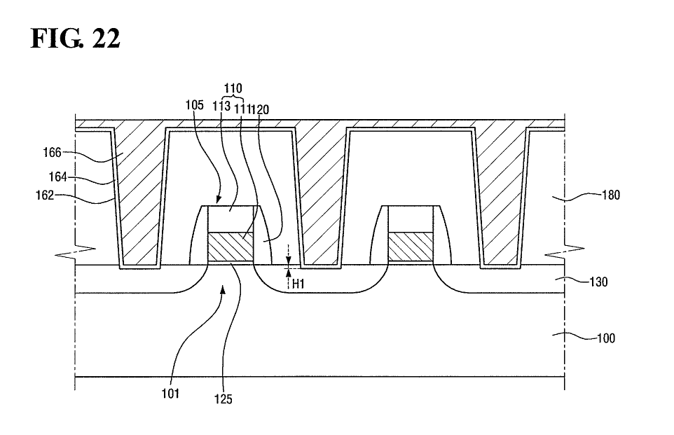

Then referring to FIG. 22, a first conductive layer 166 is formed on the first barrier metal 164. The first conductive layer 166 may be formed to completely fill the inside of the first contact hole 162. The first conductive layer 166 may include tungsten (W). However, embodiments are not limited thereto, and for example, the first conductive layer 166 may include at least one of polysilicon, metal silicide compound, conductive metal nitride, and metal.

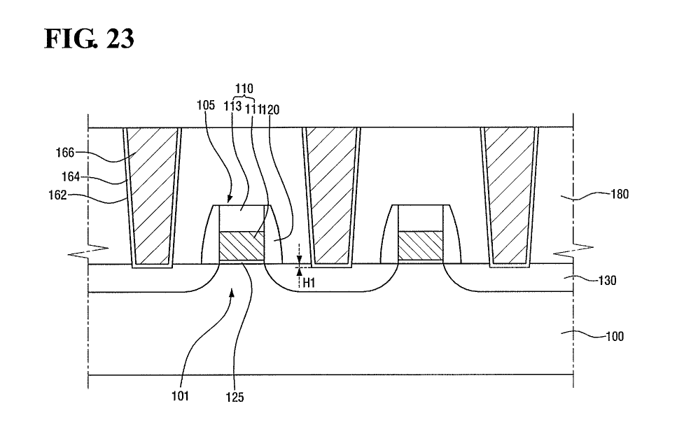

Then, referring to FIG. 23, a planarization process (e.g., CMP process) is performed so that the upper surface of the interlayer insulating layer 180 and the upper surface of the first conductive layer 166 become in parallel to each other. Through this, the upper surface of the interlayer insulating layer 180 and the upper surface of the first conductive layer 166 are positioned on the same plane.

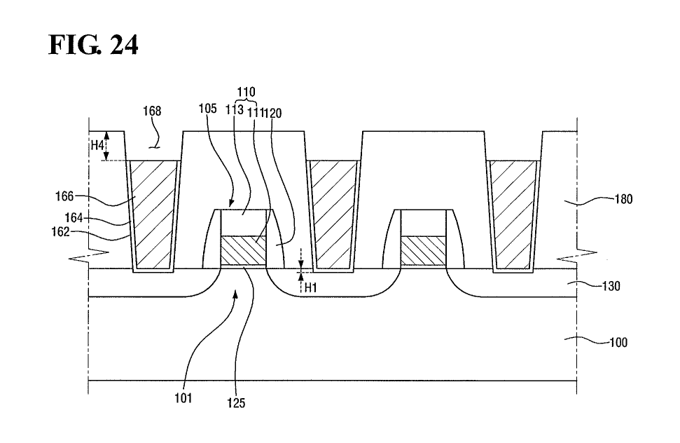

Then, referring to FIG. 24, upper portions of the first conductive layer 166 and the first barrier metal 164 are etched using an etching process. The first conductive layer 166 and the first barrier metal 164 may be etched with a fourth depth H4. Through this, a trench 168 may be formed on an upper portion of the first conductive layer 166. At this time, materials having different etch selection ratios may be used in the process of etching the interlayer insulating layer 180. Accordingly, only parts of the first conductive layer 166 and the first barrier metal 164 except for the interlayer insulating layer 180 can be etched. Specifically, an anisotropic etching may be performed through dry etching. For example, in the case of the dry etching using gases or ions that are dissolved using plasma, the anisotropic etching is performed. In the case of plasma etching, an anisotropic etching, in which the etching speed in z-direction that is bottom direction is higher than the etching speed in x-direction that is lateral direction, is performed unlike an isotropic etching, in which the etching speed in z-direction and the etching speed in x-direction are equal to each other.

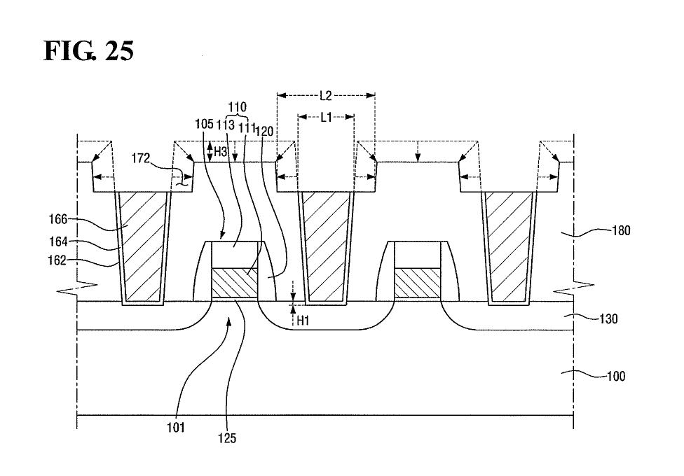

Then, referring to FIG. 25, the upper portion of the interlayer insulating layer 180 is etched through the isotropic etching. As the isotropic etching, dry etching or wet etching may be used. Mostly, in the case of the wet etching, the isotropic etching is performed, while in the case of the dry etching using reactive gases or steam, the isotropic etching is performed in the same manner as the wet etching.

The isotropic etching is performed in a state where the etching speed in the vertical direction and the etching speed in the horizontal direction are equal to each other. Accordingly, the upper portion of the interlayer insulating layer 180 is uniformly etched in the horizontal and vertical directions with a third thickness H3, and through this, a second contact hole 172 having a width that is larger than the width of the first contact hole 162 can be formed. However, since the first conductive layer 166 includes tungsten (W) or metal, the isotropic etching can be performed only up to the upper surface of the first conductive layer 166.

That is, the second contact hole 172 can expose the upper surface of the first conductive layer 166, and the lower surface of the second contact hole 172 can be positioned on the same plane as the upper surface of the first conductive layer 166. Further, the isotropic etching is performed to lower the height of the interlayer insulating layer 180 and to make the width L2 of the lower surface of the second contact hole 172 larger than the width L1 of the upper surface of the first contact hole 162.

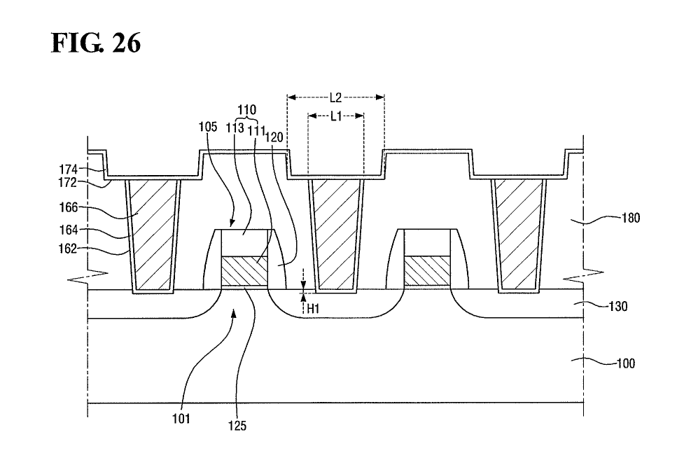

Then, referring to FIG. 26, a second barrier metal 174 is conformally formed on the second contact hole 172 and the interlayer insulating layer 180. Through this the second barrier metal 174 may be conformally formed on an inner surface of the second contact hole 172. That is, the second barrier metal 174 may be formed on both side surfaces and a lower surface of the second contact hole 172 with a predetermined thickness. The second barrier metal 174 may be formed using a PVD, CVD, or ILD method. The second barrier metal 174 may include the same material as the material of the first barrier metal 164. However, embodiments are not limited thereto.

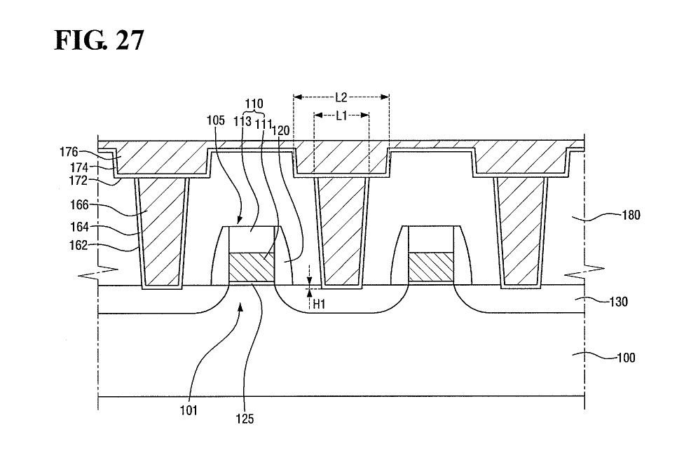

Then, referring to FIG. 27, a second conductive layer 176 is formed on the second barrier metal 174. The second conductive layer 176 may be formed to completely fill the inside of the second contact hole 172. The second conductive layer 176 may include tungsten (W). However, embodiments are not limited thereto, and for example, the second conductive layer 176 may include at least one of polysilicon, metal silicide compound, conductive metal nitride, and metal. As a result, the second barrier metal 174 may be formed between the first conductive layer 166 and the second conductive layer 176.

Then, referring again to FIG. 1, a planarization process (e.g., CMP process) is performed so that the upper surface of the interlayer insulating layer 180 and the upper surface of the second conductive layer 176 become in parallel to each other. Through this, the upper surface of the second conductive layer 176 and the upper surface of the second barrier metal 174 can be positioned on the same plane.

While embodiments have been particularly shown and described with reference to exemplary embodiments thereof, it will be understood by those of ordinary skill in the art that various changes in form and details may be made therein without departing from the spirit and scope of the embodiments as defined by the following claims. It is therefore desired that the present embodiments be considered in all respects as illustrative and not restrictive, reference being made to the appended claims rather than the foregoing description to indicate the scope of the invention.

1. A semiconductor device, comprising:
a transistor on a substrate, the transistor including a gate electrode and a source/drain;
an interlayer insulating layer covering the transistor;
a first contact hole in the interlayer insulating layer to expose a part of the transistor;
a first barrier metal conformal on an inner surface of the first contact hole;
a first conductive layer on the first barrier metal to fill the first contact hole;
a second contact hole on the first conductive layer in the interlayer insulating layer and having a larger width than the first contact hole;
a second barrier metal conformal on an inner surface of the second contact hole; and
a second conductive layer on the second barrier metal to fill the second contact hole, the second barrier metal separating between the first conductive layer and the second conductive layer.

2. The semiconductor device of claim 1, wherein a width of the second conductive layer is larger than a width of the first conductive layer, the second barrier metal completely separating the first conductive layer from the second conductive layer.

3. The semiconductor device of claim 1, wherein the second barrier metal is continuous and conformal on a bottom and sidewalls of the second contact hole, and a width of the second barrier metal on the bottom of the second contact hole is larger than a width of an uppermost end of the first contact hole.

4. The semiconductor device of claim 1, wherein the first and second contact holes have a tapered shape, respectively, sidewalls of the second contact hole being horizontally spaced apart from respective sidewalls of the first contact hole.

5. The semiconductor device of claim 1, wherein the first barrier metal is connected to the source/drain of the transistor.

6. The semiconductor device of claim 5, wherein a lower surface of the first barrier metal is lower than an upper surface of the source/drain.

7. The semiconductor device of claim 1, wherein the first and second conductive layers are electrically connected to the gate electrode of the transistor.

8. The semiconductor device of claim 1, wherein each of the first and second barrier metals includes at least one element of titanium (Ti), titanium nitride (TiN), tungsten nitride (WN), or any combination thereof.

9. The semiconductor device of claim 1, wherein each of the first and second conductive layers includes tungsten (W).

10. A semiconductor device, comprising:
a transistor on a substrate, the transistor including a gate structure and a source/drain;
an interlayer insulating layer covering the transistor;
a first contact hole in the interlayer insulating layer to expose a part of the transistor;
a first barrier metal conformal on an inner surface of the first contact hole;
a first conductive layer on the first barrier metal to fill the first contact hole;
a second contact hole on the first conductive layer in the interlayer insulating layer and having a larger width than the first contact hole;
a second barrier metal conformal on an inner surface of the second contact hole: and
a second conductive layer on the second barrier metal to fill the second contact hole,
wherein a part of a bottom of the second contact hole extends substantially horizontally beyond the first contact hole to overlap a part of a top of the gate structure, the second contact hole and the gate structure being separated from each other by the interlayer insulating layer.

11. The semiconductor device of claim 10, wherein a lower surface of the second contact hole is higher than an upper surface of the gate structure.

12. The semiconductor device of claim 10, wherein the gate structure includes at least one element of a gate insulating layer, a conductive layer, a hard mask layer, a spacer, or any combination thereof.

13. The semiconductor device of claim 10, wherein the first and second conductive layers are electrically connected to the source/drain.

14. The semiconductor device of claim 13, wherein the second contact hole on a first side of the gate structure overlaps the first side of the gate structure and is arranged to be spaced apart from an additional second contact hole on a second side of the gate structure, the additional second contact hole overlapping the second side of the gate structure.

15. A semiconductor device, comprising:
a substrate on which a first active region and a second active region are defined;
first and second gate structures on the substrate to cross the first and second active regions;
an interlayer insulating layer covering the first and second active regions and the first and second gate structures;
a first contact hole in the interlayer insulating layer to expose a source/drain in the first and second active regions or to expose the first and second gate structures;
a first barrier metal conformal on an inner surface of the first contact hole;
a first conductive layer on the first barrier metal to fill the first contact hole;
a second contact hole on the first conductive layer in the interlayer insulating layer, the second contact hole having a larger width than the first contact hole;
a second barrier metal conformal on an inner surface of the second contact hole; and
a second conductive layer on the second barrier metal to fill the second contact hole,
wherein the second barrier metal is between the first conductive layer and the second conductive layer, the first and second barrier metals being conformal on bottom and sidewalls of respective ones of the first and second contact holes.

16. The semiconductor device of claim 15, wherein the first contact hole exposes upper surfaces of the first and second gate structures, and
the upper surfaces of the first and second gate structures come in contact with a lower surface of the first barrier metal.

17. The semiconductor device of claim 15, wherein each of the first and second gate structures includes a gate insulating layer, a lower metal gate electrode, and an upper metal gate electrode, which are sequentially formed.

18. The semiconductor device of claim 15, wherein the first contact hole exposes upper surfaces of the source/drain in the first active region and the source/drain in the second active region; and
wherein the first and second conductive layers are electrically connected to the source/drain in the first and second active region.

19. The semiconductor device of claim 15, wherein each of the first and second active regions includes a first fin and a second fin.

20. The semiconductor device of claim 19, wherein each of the first and second fins includes a recess on a part of the first or second fin, and elevated source/drain formed in the recess,
wherein the first contact hole exposes the elevated source/drain.
